(19) United States
(12) Patent Application Publication
(10) Pub. No.: US 2005/0092979 A1
(43) Pub. Date: May 5, 2005

(54) Single-mode laser diode using strain-compensated multi-quantum-wells and method for manufacturing the same

(76) Inventors: Il Ki Han, Seoul (KR); Jung Il Lee, Seoul (KR); Woon Jo Cho, Uijeongbu-si (KR); Won Jun Choi, Seoul (KR); Du Chang Heo, Seoul (KR)

Correspondence Address: JONES DAY, 222 EAST 41ST ST, NEW YORK, NY, 10017, US

(21) Appl. No.: 10/942,399

(22) Filed: Sep. 16, 2004

(30) Foreign Application Priority Data
Oct. 30, 2003 (KR) 10-2003-76161

(51) Int. Cl. H01L 29/06

(52) U.S. Cl. 257/9; 257/11

(57) ABSTRACT

The present invention relates to a single-mode laser diode and a method for manufacturing the same, which utilizes strain-compensated multi-quantum-wells. The present invention provides a single-mode laser diode, comprising: a substrate; an n-type cladding layer formed on the substrate; an n-type separate-confinement heterostructure (SCH) layer formed on the n-type cladding layer, multiple quantum wells (MQWs) formed on the n-type SCH layer to generate a light in a predetermined wavelength region; a p-type SCH layer formed on the MQWs to confine the light; a p-type cladding layer formed on the p-type SCH layer to prevent loss of the light; an ohmic layer formed on the p-type cladding layer to control ohmic contact; and an electrode for injecting current to the MQWs to generate the light, wherein the n-type cladding layer prevents loss of the light and the n-type SCH layer confines the light, and wherein the MQWs are strain-compensated by a number of compressively strained well layers and a number of tensile strain barrier layers, which are formed alternatingly in a predetermined lamination cycle.

### FIELD OF THE INVENTION

The present invention relates to laser diode; and more particularly, to a single-mode laser diode and a method for manufacturing the same, which utilizes strain-compensated multi-quantum-wells comprised of a number of compressively strained well layers and a number of tensile strain barrier layers.

### BACKGROUND OF THE INVENTION

A laser diode (LD) is a light-emitting semiconductor device that emits energy equivalent to the energy bandgap in an optical form, when the electrons of n-type semiconductor in the conduction band of the energy band and the holes of p-type semiconductor in the valence band of the energy band are recombined by a current applied to the p-type and n-type semiconductors with p-n junctions. Particularly, the LD utilizes a light amplified by stimulated emission within an active layer, which is a thin layer with a small energy bandgap formed between semiconductor materials with wide energy bandgap. Therefore, when oscillation that increases coherence of light occurs, all the emitted light from the active layer is amplified with an identical direction and phase.

Generally, the active layer of the laser diode utilizes quantum well structure formed from semiconductor materials such as GaAs/AlGaAs, InGaAsP/InGaAsP or the like. In the active layer of the quantum well structure, the electrons of the conduction band and the holes of the valence band are confined in the quantum well. As a result, density of states of the carriers in the quantum well increases and thereby emission recombination rate of the electrons and the holes increases effectively. In addition, since the refractive index of the quantum well is larger than the refractive index of the semiconductor material that surrounds outside of the quantum well, photons generated from the quantum well also become confined spatially near the quantum well. In particular, a multiple quantum wells (MQWs) structure utilized in the active layer of the LD confines simultaneously the carriers and photons to the center part of the optical waveguide, and thereby decreases the threshold current of LDs by ten times and improves temperature stability which enables LDs to operate continuously at room temperature.

Meanwhile, the application field of high power LDs varies according to generated wavelength and optical output. For example, high power LDs operating at wavelength of about 1.5 μm are used in the fields of erbium-doped fiber amplifier, Raman amplifier, light source for free-space communication, laser radars, etc. There are commercialized single-mode high power LDs operating at wavelength of 1.5 μm, such as ridge-type LDs developed by Furukawa Electric co. of Japan and SDL of U.S.A., which provides optical output power of about 500 mW. However, the ridge-type laser diode had a problem that it could not provide high output power over 1 W. In addition, even though large area LDs could provide high optical output power of several watts, there was a problem that it couldn't have single-mode optical output characteristics in the form of Gaussian distribution because of filamentation.

To manufacture LDs that provide high optical output power and single-mode optical output power, tapered LDs, MOPA (Master Oscillator Power Amplifier), angled-grating distributed feedback lasers have been developed. Among them, tapered LDs are mainly used because of the easy fabrication process and inexpensive price.

FIG. 1 is a schematic diagram of the typical structure of the tapered LD. As shown in FIG. 1, tapered LD 1 is separated into a ridge section 3 to generate light with single-mode characteristics and a tapered gain section 5 to obtain sufficient optical gain. The light generated from the ridge section 3 is amplified in the tapered gain section 5, and thereby the tapered LD provides single-mode light with high output power [D. F. Welch et al., Electron. Lett. vol. 28, p. 2011, 1992].

SDL of U.S.A. developed a single-mode tapered LD operating at 1.5 μm, which provide a maximum optical output power of CW(Continuous Wave) 2.35 W and a single-mode optical output power of CW 1.8 W, by utilizing compressively strained InGaAsP/InP MQWs in the taper LD structure as shown in FIG. 1 [A. Mathur et al., Electron. Lett. vol. 35, p. 983, 1999]. Alcatel of France also developed single-mode tapered LDs operating at 1.5 μm, which provide a maximum optical output power of CW 1.5 W and a single-mode optical output power of CW 1.2 W, by utilizing compressively strained InGaAsP/InP MQWs [S. Delepine et al., Electron. Lett. vol. 36, p. 221, 2000]. Also, Lincoln Lab. of MIT in USA developed single-mode tapered LDs operating at 1.5 μm, which provide a maximum optical output power of CW 1.0 W and a single-mode optical output power of CW 0.8 W, by utilizing compressively strained InGaAsP/InP MQWs [J. P. Donnelly et al., IEEE Photon. Technol. Lett. vol. 10, p. 1377, 1998]. In Korea, KIST developed single-mode tapered LDs operating at 1.5 μm, which provide a maximum optical output power of CW 0.8 W and a single-mode optical output power of CW 0.56 W, by utilizing high p-doping and compressively strained InGaAsP/InGaAs/InP MQWs [I. K. Han et al., J. Kor. Phys. Soc. vol. 38. p. 177, 2001].

However, since the compressively strained MQWs structure of single-mode tapered LDs have non-uniform hole distributions, there is a high possibility that non-radiative Auger recombination, which is proportional to n³ (where n is the number of electrons or holes), may take place in the energy band with high hole concentration. When Auger recombination increases, thermal energy within the MQWs also increases, thereby reducing quantum efficiency and optical output power.

### SUMMARY OF THE INVENTION

Therefore, the object of the present invention is to solve the problems above. In particular, the object of the present invention is to provide a single-mode laser diode and a method for manufacturing the same, which utilizes epi-structure with strain-compensated MQWs comprised of a number of compressively strained well layers and a number of tensile strain barrier layers to reduce the possibility of Auger recombination in MQWs, and improves temperature stability of MQWs to increase a maximum optical output power and a single-mode optical output power.

According to an aspect of the present invention to achieve the above objects, the present invention provides a single-mode laser diode, which comprises: a substrate; an n-type cladding layer formed on the substrate; an n-type Separate-Confinement Heterostructure (SCH) layer formed on the n-type cladding layer, multiple quantum wells (MQWs) formed on the n-type SCH layer to generate light in a predetermined wavelength region; a p-type SCH layer formed on the MQWs to confine light; a p-type cladding layer formed on the p-type SCH layer to prevent loss of light; an ohmic layer formed on the p-type cladding layer to control ohmic contact; and an electrode for injecting current to the MQWs to generate light, wherein the n-type cladding layer prevents loss of light and the n-type SCH layer confines light; and wherein the MQWs are strain-compensated by a number of compressively strained well layers and a number of tensile strain barrier layers, which are formed alternatingly in a predetermined lamination cycle.

According to another aspect of the present invention to achieve the above objects, the present invention provides a method for manufacturing a single-mode laser diode, which comprises: preparing a substrate; forming an n-type cladding layer on the substrate; forming an n-type separate-confinement heterostructure (SCH) layer on the n-type cladding layer, forming multiple quantum wells (MQWs) on the n-type SCH layer to generate light in a predetermined wavelength region; forming a p-type SCH layer on the MQWs to confine light; forming a p-type cladding layer on the p-type SCH layer to prevent loss of light; forming an ohmic layer on the p-type cladding layer to control ohmic contact; and forming an electrode for injecting current to the MQWs to generate light, wherein the n-type cladding layer prevents loss of light and the n-type SCH layer confines light; and wherein the MQWs are strain-compensated by a number of compressively strained well layers and a number of tensile strain barrier layers, which are formed alternatingly in a predetermined lamination cycle.

### BRIEF DESCRIPTION OF THE DRAWINGS

FIG. 1 is a schematic diagram of the typical structure of the tapered laser diode.

FIGS. 2a and 2b are schematic diagrams of the energy band and the doping concentration of the epi-structure having strain-compensated multi-quantum-wells.

FIG. 3 is a schematic diagram of the epi-structure having strain-compensated multi-quantum-wells of the single-mode tapered laser diode according to the present invention.

FIGS. 4a-4f illustrate a method for forming an electrode of the single-mode tapered laser diode according to the present invention.

FIG. 5 is a graphic diagram of optical output power of the single-mode tapered laser diode according to the present invention.

FIG. 6 is a graphic diagram illustrating the Gaussian profile fitting of the far-field optical intensity distributions of the single-mode tapered laser diode according to the present invention.

FIG. 7 is a graphic diagram of the single-mode optical output power of the single-mode tapered laser diode according to the present invention.

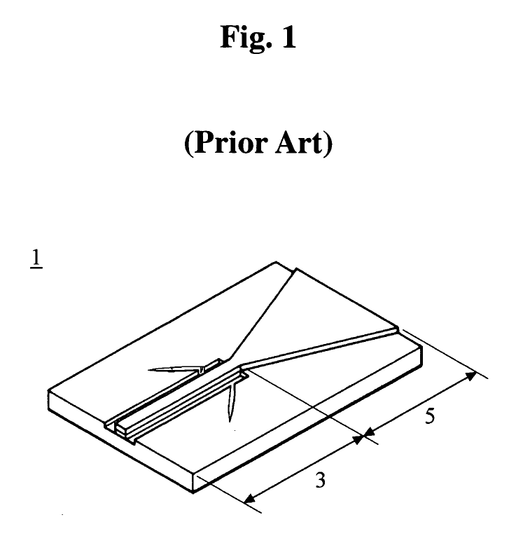

### DETAILED DESCRIPTION OF THE INVENTION

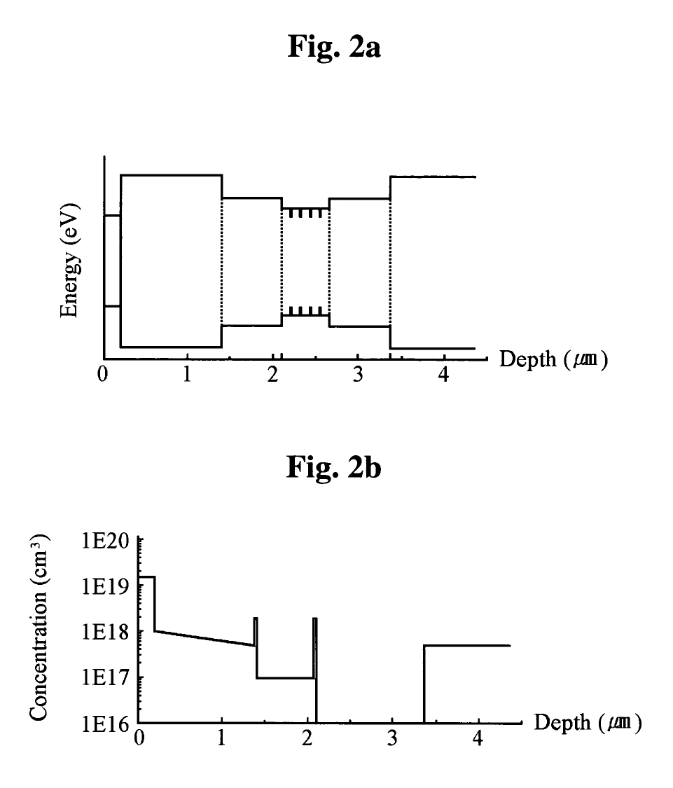

The preferred embodiments of the present invention will now be described in detail with reference to FIGS. 2-7. Since the typical structure of single-mode tapered LD is similar to that of the prior art, the epi-structure having strain-compensated MQWs, which is used in the single-mode tapered LDs, will be mainly discussed.

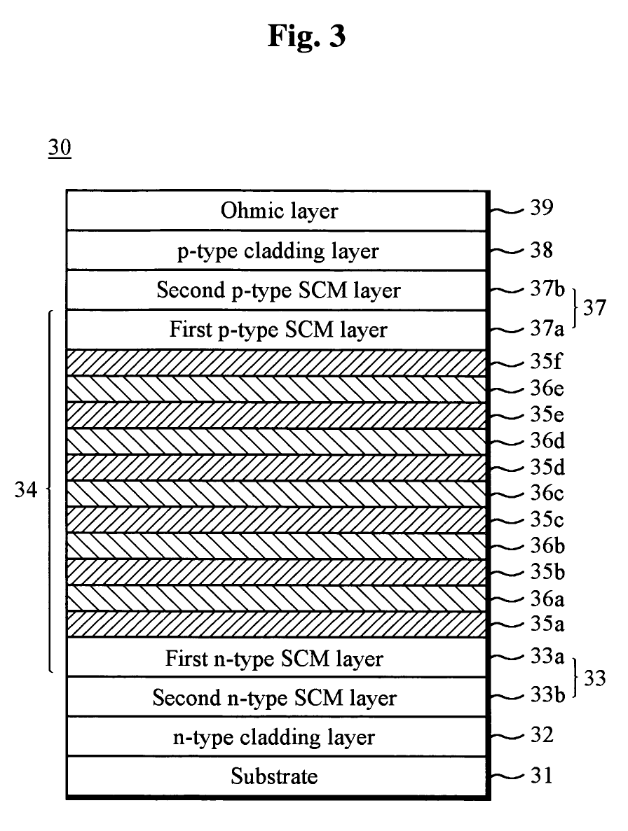

FIGS. 2a and 2b are schematic diagrams of the energy band and the doping concentration of the epi-structure having strain-compensated MQWs, which is used in the single-mode tapered LD according to an embodiment of the present invention. As shown in FIGS. 2a and 2b, the epi-structure comprises an n-type cladding layer 32 with a doping concentration of 5×10¹⁷/cm³, an n-type SCH layer 33, MQWs 34, a p-type SCH layer 37 with a doping concentration of 1×10¹⁷/cm³˜2×10¹⁸/cm³, a p-type cladding layer 38 with a doping concentration of 5×10¹⁷/cm³˜2×10¹⁸/cm³. The epi-structure is described in more detail below with reference to FIG. 3.

As shown in FIG. 3, the epi-structure 30 utilized in the present invention includes a substrate 31, an n-type cladding layer 32, an n-type SCH layer 33, well layers 35a-35f, barrier layers 36a-36e, a p-type SCH layer 37, a p-type cladding layer 38 and an ohmic layer 39, and the epi-structure 30 is formed by typical epi-growth techniques, such as, Metal Organic Chemical Vapor Deposition (MOCVD), Gas Source Molecular Beam Epitaxy (GSMBE), Chemical Beam Epitaxy (CBE), etc.

Initially, InP, which is grown to be 350 μm thick, is used as the n+ type substrate 31. Then, the n-type cladding layer 32 is formed on the n+ type substrate 31 by growing 1 μm-thick-InP, which is doped with Si with a concentration of 5×10¹⁷/cm³. The n-type cladding layer 32 and the p-type cladding layer 38, described below, serve to prevent the loss of light that takes place in the thin MQWs 34. The MQWs 34 are comprised of well layers 35a-35f, barrier layers 36a-36e, a first n-type SCH layer 33a and a first p-type SCH layer 37a to be described below, and the MQWs 34 function as a active layer that emits light.

The n-type SCH layer 33 is divided into the first n-type SCH layer 33a and the second n-type SCH layer 33b according to the composition of constituent materials. The second n-type SCH layer 33b is formed on the n-type cladding layer 32 by growing 700 nm-thick-InGaAsP. The second n-type SCH layer 33b, with the second p-type SCH layer 37b described below, serve as optical waveguides, which is to generate single-mode oscillation by confining the light of a specific wavelength region emitted from the MQWs 34. Generally, the n-type and p-type SCH layers are grown to be about 140 nm thick. However, in the embodiment of the present invention, the SCH layers are grown to be more than 700 nm thick, and thereby effectively confine the light emitted form the MQWs 34. As described above, distributions of the light emitted form the MQWs 34 can be controlled by changing the composition of the materials forming the n-type and p-type SCH layers 33, 37, and varying the thickness grown in the n-type and p-type SCH layers 33, 37.

The first n-type SCH layer 33a is formed on the second n-type SCH layer 33b by growing 10 nm-thick-InGaAsP, wherein the energy gap wavelength of quaternary InGaAsP is 1.25 μm. The first n-type SCH layer 33a, with the first p-type SCH layer 37a described below, serve as a barrier layer that constitutes strain-compensated MQWs 34.

A first well layer 35a that constitutes MQWs 34 is formed on the first n-type SCH layer 33a by growing 6.5 nm-thick-InGaAsP, wherein the energy gap wavelength of quaternary InGaAsP is 1.6 μm. Further, a first barrier layer 36a that constitutes MQWs 34 is formed on the first well layer 35a by growing 10 nm-thick-InGaAsP, wherein the energy gap wavelength of quaternary InGaAsP is 1.25 μm. As shown in FIG. 3, the second to sixth well layers 35b-35f and the second to fifth barrier layers 36b-36e, which are grown alternatingly in a predetermined lamination cycle, are formed in the same process as described above, and accordingly, the description thereof is omitted here.

As described above, the MQWs 34 are comprised of the first n-type SCH layer 33a, well layers 35a-35f, barrier layers 36a-36e, and a first p-type SCH layer 37a described below. When the MQWs 34 emit light of wavelength 1.5 μm, the thickness of the well layers 35a-35f is compressed by about 0.8% and the thickness of the barrier layers 36a-36e is strained by about 0.5% by the composition change in InGaAsP materials forming the well layers and barrier layers, and thereby the strain of the MQWs 34 is compensated. As a result, the bandgap offset, which is the energy difference between the well layers 35a-35f and the barrier layers 36a-36e in the valence band of MQWs 34, is reduced to make uniform hole distribution within MQWs 34, and thereby the possibility of Auger recombination is decreased, thermal energy generation within MQWs 34 is effectively restrained, and consequently quantum efficiency is improved. This strain-compensated MQWs 34 can control the extent of strain compensation by varying the composition of the materials forming the well layers 35a-35f and the barrier layers 36a-36e.

The p-type SCH layer 37 is divided into a first p-type SCH layer 37a and a second p-type SCH layer 37b according to the composition of constituent materials. Initially, the first p-type SCH layer 37a is formed on the sixth well layer 35f that constitutes MQWs 34 by growing 10 nm-thick-InGaAsP, wherein the energy gap wavelength of quaternary InGaAsP is 1.25 μm. The first p-type SCH layer 37a, with the first n-type SCH layer 33a, serves as a barrier layer that constitutes strain-compensated MQWs 34.

The second p-type SCH layer 37b is formed on the first p-type SCH layer 37a by growing InGaAsP doped with Zn. In this case, the second p-type SCH layer 37b is formed by growing 20 nm-thick-InGaAsP, which is doped with Zn with a concentration of 2×10¹⁸/cm³, and then further growing 680 nm-thick-InGaAsP, which is doped with Zn with a concentration of 1×10¹⁷/cm³, once more. Particularly, Zn doped in the second p-type SCH layer 37b with a concentration of 2×10¹⁸/cm³ serves to suppress the leakage current caused by the electrons in the conduction band of MQWs 34. Although high concentration Zn is doped into the material that is grown right on the first p-type SCH layer 37a in the embodiment of the present invention, doping position and doping concentration can be varied and are not restricted to such position and concentration. As described above, threshold current and quantum efficiency of single-mode tapered LDs can be controlled by varying the doping position and doping concentration of the impurities doped in the second p-type SCH layer 37b and thereby suppressing the leakage current of MQWs 34.

The p-type cladding layer 38 is formed on the second p-type SCH layer 37b by growing 20 nm-thick-InP, which is doped with Zn with a concentration of 2×10¹⁸/cm³, and then further growing 1.2 μm-thick-InP once more, which is doped with Zn with a concentration of 5×10¹⁷/cm³˜1×10¹⁸/cm³. The p+ type ohmic layer 39, which can control ohmic contact, is formed on the p-type cladding layer 38 by growing 200 nm-thick-Ga_{0.47}In_{0.53}As, which is doped with Zn with a concentration of more than 1.5×10¹⁹/cm³. The epi-structure 30 described above is formed by a typical MOCVD technique that is used for InP-based epi-structure.

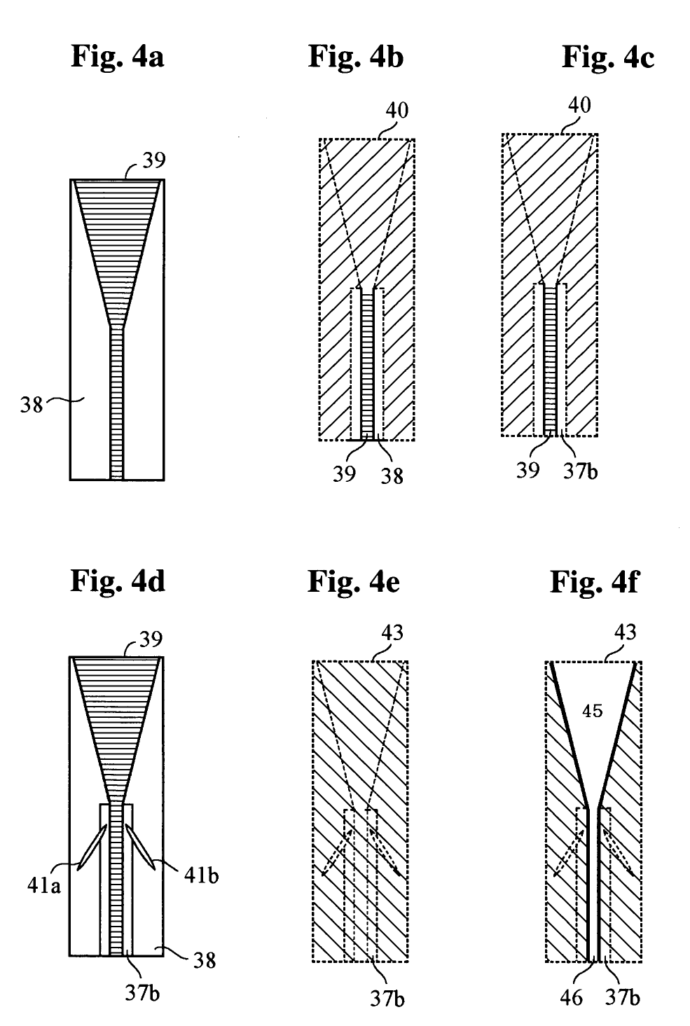

FIGS. 4a-4f schematically illustrate a process for forming an electrode of the single-mode tapered laser diode by utilizing the epi-structure 30 shown in FIG. 3. First, the ohmic layer 39 of the epi-structure shown in FIG. 3 is etched by a mixture of one part of H₃PO₄, one part of H₂O₂, and eight parts of H₂O to form a structure shown in FIG. 4a. Then, after a mask 40 with a shape represented by the dotted region in FIG. 4b is formed, the p-type cladding layer 38 is etched by a mixture of one part of HCl and one part of H₃PO₄. Then, the second p-type SCH layer 37b is etched to a depth of about 300 nm by applying Reactive Ion Etching (RIE) technique until single-mode oscillation condition is satisfied, and thereby the ridge section of the single-mode tapered LD is formed (FIG. 4c). The mask is then removed to etch deep grooves 41a, 41b (FIG. 4d), and an insulation film 43 is formed by utilizing spin-on-glass (SOC) (FIG. 4e). Then, after opening the tapered section and ridge section with photolithography technique, the opened SOG 45, 46 is etched using RIE technique (FIG. 4f). Following the opening process (FIG. 4f), an electrode, which can inject current to the semiconductor material, is formed by depositing and thermal-processing a p-type metal on the tapered section and ridge section, and then substrate thinning, n-type metal deposition and thermal processing processes are performed successively. The manufacturing process after the opening process is identical to the typical process for forming an electrode of LD, and thus detailed description thereof is omitted.

However, the groove etching process (FIG. 4d) may be omitted to simplify the process of forming the electrode of the single-mode tapered laser diode. In this case, after the ridge section is formed (FIG. 4c), an insulation film of about 3 μm thick is formed by depositing Silicon Nitride (SiNx) film using Plasma Enhanced Chemical Vapor Deposition (PECVD) technique. Then, after the tapered section and the ridge section are opened with photolithography technique, the opened SiNx film is etched by buffered HF solution, and the following manufacturing process is the same as described above.

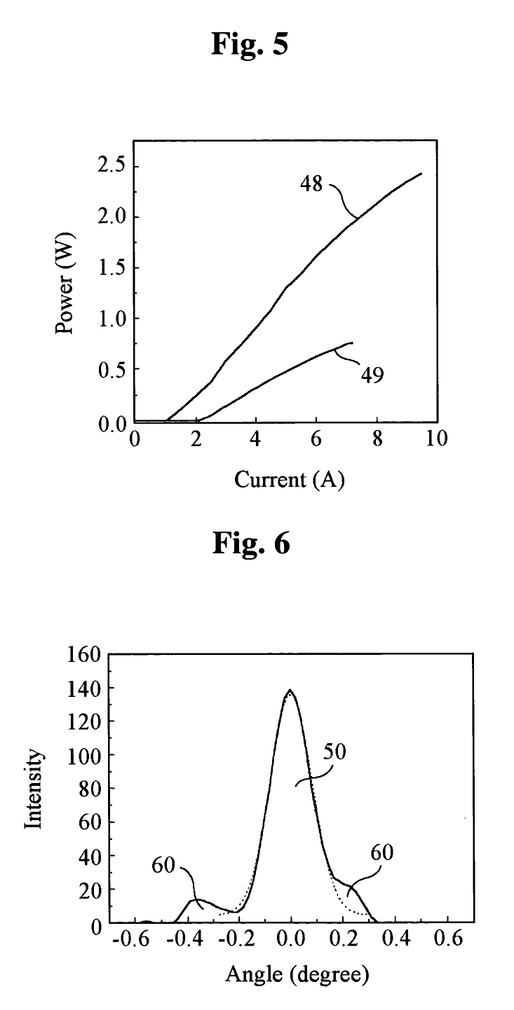

FIG. 5 is a graphic diagram illustrating the optical output power for the injection current of the single-mode tapered LD according to an embodiment of the present invention. As shown in FIG. 5, the maximum optical output power 48 of the single-mode tapered LD utilizing strained compensated MQWs is measured to be CW 2.45 W at room temperature of 15° C., and this shows that the maximum optical output power increased to about 3 times the maximum optical output power 49, CW 0.8 W of the single-mode tapered LD utilizing compressively strained MQWs [I. K. Han et al., J. Kor. Phys. Soc. vol. 38. p. 177, 2001]. Also, the slope efficiency, which represents the change in the optical output power with respect to the change in the current injected to the single-mode tapered LD, is measured to be 34%, which is increased about 2 times from 18%.

FIG. 6 is a graphic diagram of the far-field optical intensity distributions of the single-mode tapered LD according to the present invention. The solid line shown in FIG. 6 is the far-field optical intensity distributions measured by injecting 3 A-current to the single-mode tapered LD, and the dotted line represents the Gaussian profile fitting of the measured far-field optical intensity distributions. The area 50 inside the dotted line, which occupies about 90% of the whole area, represents single-mode optical output power, and the area 60 between the solid line and the dotted line, which occupies about 10% of the whole area, corresponds to the optical output power resulted from filamentation. Generally, the optical output power by filamentation is filtered by lens or pin-hole and the like.

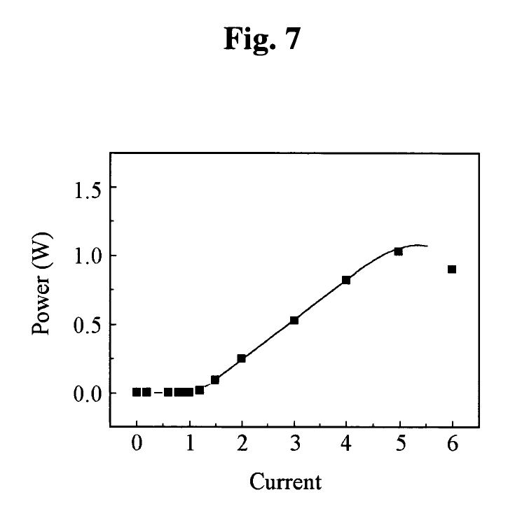

FIG. 7 is a graphic diagram of the single-mode optical output power with respect to the increase in the current injected to the single-mode tapered laser diode according to the present invention. After measuring the far-field optical output power according to the increase in the injection current, and then extracting and measuring only the single-mode optical output power, the maximum single-mode optical output power over CW 1 W could be obtained at injection current of 5 A. It can be appreciated that the maximum single-mode optical output power increased to about 2 times the maximum single-mode optical output power, CW 0.56 W of the single-mode tapered LD utilizing compressively strained MQWs [I. K. Han et al., J. Kor. Phys. Soc. vol. 38. p. 177, 2001].

The present invention utilizes the epi-structure, which has strain-compensated MQWs comprised of a number of compressively strained well layers and a number of tensile strain barrier layers, in the single-mode tapered LD, and thereby reduces the possibility of Auger recombination in MQWs, increases quantum efficiency by further improving temperature stability of MQWs, and can increase maximum optical output power and single-mode optical output power of the single-mode tapered LD.

It should be appreciated that the embodiments descried above represent only the parts of various embodiments to which the principle of the present invention is applied. It would be understood clearly that a person skilled in the art is capable of using a variety of modifications without departing from the substance of the present invention.

1. A single-mode laser diode, comprising:
a substrate;
an n-type cladding layer formed on the substrate;
an n-type separate-confinement heterostructure (SCH) layer formed on the n-type cladding layer,
multiple quantum wells (MQWs) formed on the n-type SCH layer to generate a light in a predetermined wavelength region;
a p-type SCH layer formed on the MQWs to confine the light;
a p-type cladding layer formed on the p-type SCH layer to prevent loss of the light;
an ohmic layer formed on the p-type cladding layer to control ohmic contact; and
an electrode for injecting current to the MQWs to generate the light,
wherein the n-type cladding layer prevents loss of the light and the n-type SCH layer confines the light,
and wherein the MQWs are strain-compensated by a number of compressively strained well layers and a number of tensile strain barrier layers, which are formed alternatingly in a predetermined lamination cycle.

2. The single-mode laser diode as claimed in claim 1, wherein extent of strain compensation is controlled by the MQWs by varying a composition of semiconductor materials forming the number of compressively strained well layers and the number of tensile strain barrier layers.

3. The single-mode laser diode as claimed in claim 1, wherein,
each of the n-type SCH layer and the p-type SCH layer includes a first SCH layer and a second SCH layer, wherein semiconductor materials constituting the first SCH layer and the second SCH layer have different energy gap wavelengths,
the first n-type SCH layer is formed on one side of the MQWs and the first p-type SCH layer is formed on the other side of the MQWs, wherein the other side is opposite to the one side of the MQWs, and
the second n-type SCH layer and the second p-type SCH layer are formed to surround the first n-type SCH layer and the first p-type SCH layer, and thereby the n-type SCH layer and the p-type SCH layer confine the light generated from the MQWs so that single-mode oscillation is obtained.

4. The single-mode laser diode as claimed in claim 3, wherein a leakage current is controlled by varying doping position and doping concentration of impurities doped in the semiconductor materials constituting the second p-type SCH layer.

5. The single-mode laser diode as claimed in claim 1, wherein the electrode is formed on a ridge section to obtain single-mode oscillation of the light generated from the MQWs and a tapered gain section to amplify the single-mode light.

6. A method for manufacturing a single-mode laser diode, comprising:
preparing a substrate;
forming an n-type cladding layer on the substrate;
forming an n-type separate-confinement heterostructure (SCH) layer on the n-type cladding layer;
forming multiple quantum wells (MQWs) on the n-type SCH layer, wherein the MQWs generate a light in a predetermined wavelength region;
forming a p-type SCH layer on the MQWs to confine the light;
forming a p-type cladding layer on the p-type SCH layer to prevent loss of the light;
forming an ohmic layer on the p-type cladding layer to control ohmic contact; and
forming an electrode for injecting a current to the MQWs to generate the light,
wherein the n-type cladding layer prevents loss of the light and the n-type SCH layer confines the light,
and wherein the MQWs are strain-compensated by a number of compressively strained well layers and a number of tensile strain barrier layers, which are formed alternatingly in a predetermined lamination cycle.

7. The method of claim 6, wherein extent of strain compensation is controlled by the forming of the MQWs by varying a composition of semiconductor materials forming the number of compressively strained well layers and the number of tensile strain barrier layers.

8. The method of claim 6, wherein,
each of forming the n-type SCH layer and forming the p-type SCH layer includes forming a first SCH layer and forming a second SCH layer, wherein semiconductor materials constituting the first SCH layer and the second SCH layer have different energy gap wavelengths,
the first n-type SCH layer is formed on one side of the MQWs and the first p-type SCH layer is formed on the other side of the MQWs, wherein the other side is opposite to the one side of the MQWs, and
the second n-type SCH layer and the second p-type SCH layer are formed to surround the first n-type SCH layer and the first p-type SCH layer, and thereby the n-type SCH layer and the p-type SCH layer confine the light generated from the MQWs so that single-mode oscillation is obtained.

9. The method of claim 8, wherein a leakage current is controlled by varying doping position and doping concentration of impurities doped in the semiconductor materials constituting the second p-type SCH layer.

10. The method of claim 6, wherein forming the electrode includes:
forming a ridge section to obtain single-mode oscillation of the light generated from the MQWs; and
forming a tapered gain section to amplify the single-mode light.
